(19) United States
(12) Patent Application Publication
(10) Pub. No.: US 2013/0209703 A1
(43) Pub. Date: Aug. 15, 2013

(54) HOLLOW-CATHODE GAS LANCE FOR THE INTERIOR COATING OF CONTAINERS

(71) Applicant: KRONES AG, (US)

(72) Inventor: Jochen Krüger, Hagelstadt (DE)

(73) Assignee: KRONES AG, Neutraubling (DE)

(21) Appl. No.: 13/751,334

(22) Filed: Jan. 28, 2013

(30) Foreign Application Priority Data
Feb. 9, 2012 (DE) 102012201956.1

(51) Int. Cl. C23C 16/455

(52) U.S. Cl. CPC C23C 16/45578
USPC 427/569; 118/723 R

(57) ABSTRACT

The disclosure relates to an apparatus for coating a container, for instance a plastic bottle, by means of a plasma treatment, the apparatus comprising at least one high-frequency source, at least one outer electrode located outside the container to be treated, and at least one at least partially electrically conducting gas lance for the supply of process gas into the container, configured to apply a high frequency of the high frequency source to the at least one outer electrode or the at least one gas lance. The gas lance is configured at least in part or in whole as a hollow cathode having at least one internal hollow space. The hollow space of the hollow cathode is fluidically connected to the interior of the container to be treated and to the part of the gas lance that supplies the process gas, for instance, by lateral and/or axial bores or recesses. A plasma can be generated in the interior of the hollow cathode in the at least one hollow space.

### BACKGROUND

In order to reduce the permeability of container walls/walls of hollow bodies, for instance with regard to undesired substances, it is advantageous to provide them with a barrier layer, e.g. by means of plasma-enhanced chemical vapor deposition (PECVD) as is described, for instance, in EP0881197A2.

For the coating of containers by means of a plasma treatment, e.g. the interior plasma coating of plastic bottles, a so-called high-frequency plasma may, inter alia, be used.

In this connection, for instance, a plasma is generated in a container by evacuating the interior of the container to a pressure in the range of 1-10 Pa and exposing it to a high-frequency field. By means of a gas lance it is possible to introduce a gas mixture, for instance consisting of a silicon monomer and oxygen, into the interior of the container. This gas flow allows the pressure inside the container to increase by some 10 Pa so that it can be in the range of 10-30 Pa or more.

A flat electrode may be located outside the container, which can be supplied with high frequency, e.g. 13.56 MHz. The gas lance, which may simultaneously also be the electrode, is usually made of metal and is grounded by a connection to the machine housing as is described, for instance, in WO2009026869.

The high frequency couples to the gas lance, and a plasma can be ignited inside the container. The process gas may be uniformly distributed in the container through a plurality of suitably positioned bores in the gas lance, thus obtaining a uniform coating inside the container.

However, this kind of high-frequency coupling is not suited for the coating of large surfaces, e.g. the inside of bottles, at high deposition rates of more than >2 nm/s, as this requires a high gas flow and, as a consequence, a high electrical power in the form of high frequency. Moreover, plasmas that are excited with a high frequency usually have a lower plasma density than plasmas that are excited, for instance, with microwaves. This, too, may have a negative effect on the duration and efficiency of the coating method.

Therefore, it is an object of the present disclosure to improve an apparatus for coating containers by means of a plasma treatment, e.g. the plasma-enhanced coating of plastic bottles, in particular with regard to power and efficiency.

### SUMMARY

According to some aspects of the disclosure, this is achieved by an apparatus according to claim 1 and a method according to claim 8. Advantageous embodiments and further developments are described in the dependent claims.

An apparatus for coating a container, for instance a plastic bottle, by means of a plasma treatment may include at least one high-frequency source, at least one outer electrode located outside the container to be treated, and at least one at least partially electrically conducting gas lance for the supply of process gas into the container. The high frequency generated by the high frequency source may optionally be applied to the at least one outer electrode or the at least one gas lance. The gas lance may be characterized in that it may be configured at least in part or in whole as a hollow cathode having at least one internal hollow space, wherein the at least one hollow space of the hollow cathode may be fluidically connected to the interior of the container to be treated and to the part of the gas lance that supplies the process gas, for instance, by lateral and/or axial bores or recesses, and that a plasma can be generated in the interior of the hollow cathode in the at least one hollow space.

Upon the ignition of the plasma a plasma boundary sheath may develop around the gas lance, which can advantageously penetrate into the hollow cathode/the hollow space of the hollow cathode by said fluidic connection from the interior of the container to the at least one hollow space of the hollow cathode, for instance, through a hole or recess in the gas lance. In the interior of the hollow cathode plasma boundary sheaths of opposing walls may overlap, which may result in reciprocating motions of the electrons. Thus, the electrons are able to receive plenty of energy and, advantageously, a very intensive plasma may develop with which the container can be coated faster and more effectively. The plasma density in the interior of the hollow cathode may be above the plasma density in the purely capacitively coupled plasma outside the hollow cathode by 1-2 orders of magnitude, which supports the conversion of the gas mixture.

The arrangement according to the disclosure described herein permits a clear improvement of the efficiency of the process gas conversion, that is, for instance the disintegration of hexamethyldisiloxane (HMDSO), which shows in the clearly reduced CH3 content in the produced coating. CH3 is contained in the HMDSO molecule and is separated from the silicon upon the dissociation thereof. If the HMDSO is dissociated or disintegrated incompletely this methyl group is incorporated in the layer, which may result in softer coatings that have a clearly weaker barrier effect.

The higher plasma density achievable by an apparatus according to the disclosure, as compared to plasma-enhanced apparatuses for the coating of containers in high-frequency fields without the hollow-cathode plasma generation, can thus advantageously improve the degree of dissociation of HMDSO, and thus also the quality of the coating and the barrier effect thereof.

The part of the gas lance that is not configured as a hollow cathode may include bores or recesses, which are preferably arranged on the side and/or axially, e.g. with average bore diameters or recess diameters >0.5 mm, preferably 1-2 mm, through which process gas, e.g. an oxygen-monomer mixture, can be supplied into the interior of the container and/or into the at least one hollow space of the hollow cathode.

Advantageously, the gas lance may comprise an internal hollow space, for instance, with an average internal diameter of 2-20 mm, preferably 6 mm, along the entire length of the gas lance, e.g. 50-500 mm, preferably 200-300 mm, and the internal hollow space may be provided with bores or recesses, which are preferably arranged on the side and/or axially, e.g. with average bore diameters or recess diameters >0.5 mm, preferably 1-2 mm. This has the advantage that a plasma can be generated in the interior of the gas lance, i.e. in the internal hollow space, along the entire length of the gas lance, and that the plasma can flow out through said bores and recesses along the entire length of the gas lance so as to be capable of coating the container more effectively.

Additionally, the gas lance may be mounted to be rotatable so that once the plasma has been generated in the interior of the gas lance, the plasma can be distributed in the container more uniformly and faster so as to obtain a more uniform coating.

The dimensioning of a hollow cathode and the interior hollow space, respectively, results in the first approximation from the ignition condition for a plasma according to the Paschen curve, which defines the breakdown voltage V as a function of the product of pressure p and electrode distance d: V=f(p*d). Ideal ignition conditions are provided in the range p*d=1−10 hPa*cm.

From this follows by way of example that at a pressure of 100 Pa the ideal internal diameter of a hollow cathode or the internal hollow space is in the range of 1 cm≦d≦10 cm. If plasma-enhanced coating methods using high frequency are employed the pressure in the container is usually at about 10-30 Pa, however, as was already mentioned before. From this follows that the hollow cathode should have an internal diameter of some centimeters. It may be impractical or even technically impossible, however, to introduce so dimensioned hollow cathodes into a container. In order to realize smaller hollow-cathode internal diameters, e.g. d≦1 cm, the pressure has to be increased correspondingly in the region of the hollow cathode, for instance, by a gas flow into the hollow cathode. According to the present disclosure, this is achieved by the possibility to connect the hollow cathode or the internal hollow space fluidically to the part of the gas lance that supplies the process gas, so that inflowing process gas can increase the pressure in the region of the hollow cathode/of the internal hollow space, for instance, to pressures ≧100 or 200 Pa.

For a possible coating of the container with silicon oxide, for instance, a mixture of HMDSO and oxygen may be used as process gas. In principle, also mixtures of oxygen and other silicon-containing monomers are suited, however. Also, it is possible to precipitate carbon-containing layers (so-called diamond-like carbon “DLC” layers) by disintegrating a carbon-containing gas, such as acetylene, methane etc. in the plasma.

Depending on the flow the disintegrated process gas can flow out of the hollow cathode and be distributed in the container, where the correspondingly produced particles can be precipitated on the container wall.

Moreover, it is conceivable to introduce, instead of a process gas, a neutral, non-coating inert gas, such as argon or, for instance, a mixture of oxygen and argon, into the hollow cathode or internal hollow space, respectively. This has the advantage that an undesired coating of the interior of the hollow cathode can be minimized. In this case, a process gas plasma burning in the outer region of the hollow cathode can be “fed” by a hollow-cathode plasma which was generated from a neutral, non-coating inert gas. To this end, the gas lance may be adapted to allow the physically separated supply of process gas and a neutral, non-coating inert gas, wherein the process gas can be supplied directly to the container and the neutral, non-coating inert gas can be supplied directly to the hollow cathode or the internal hollow space, respectively.

As was mentioned above, a hollow-cathode plasma may be very intensive and have a high plasma density, which may be higher than that of a purely capacitively coupled plasma, for instance, by a factor 10 to 100. The plasma then streaming out of the hollow cathode into the bottle has a high fraction of charged particles and radicals. If this reactive plasma mixes outside the hollow cathode with a process gas plasma or the process gas, respectively, the latter can be disintegrated more efficiently, and a more efficient layer formation on the container wall can be obtained.

### BRIED DESCRIPTION OF THE DRAWINGS

The appended figures show by way of example:

FIG. 1: container coating apparatus

FIG. 2a: gas lance

FIG. 2b: gas lance

FIG. 3: gas lance

FIG. 4: gas lance

FIG. 5: gas lance

### DETAILED DESCRIPTION

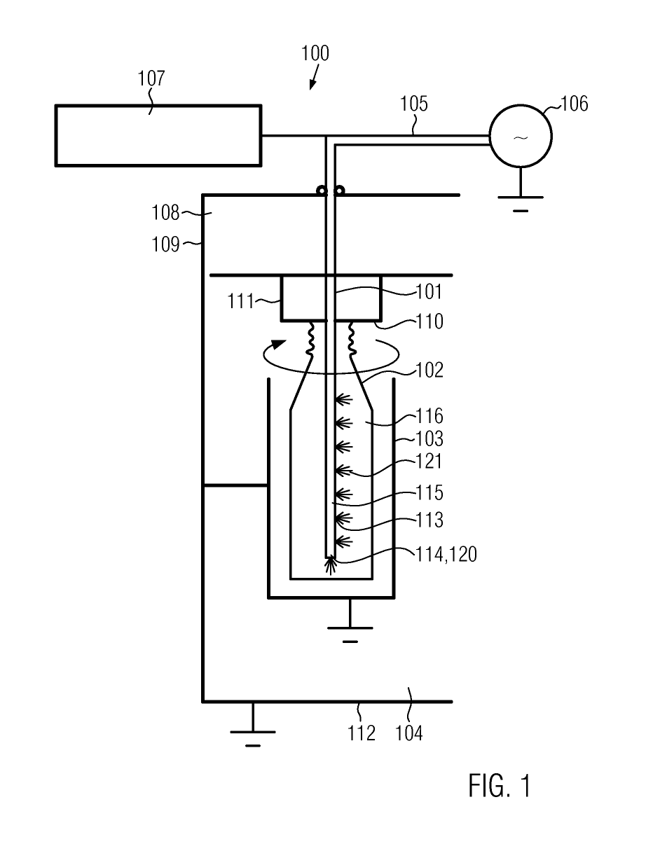

FIG. 1 shows by way of example an apparatus 100 for the plasma-enhanced coating of a container 102. The apparatus 100 may comprise two different pressure regions, e.g. a basic pressure chamber 104, which can be evacuated, for instance, to pressures of 100 to 4000 Pa, and a process pressure chamber 108 with pressures, for instance, of 1 to 30 Pa. A high-frequency source 106 may introduce high frequency through a line 105 into a gas lance 101. The line 105 may additionally serve to supply gas from a gas source 107 to the gas lance 101.

The basic pressure chamber 104 may comprise an outer electrode 103, e.g a U-shaped one, which can enclose the container 102 to be treated at least in part without contacting the container 102, as the container 102 may be suspended, for instance, by a bottle clamp 110. The outer electrode 103 may be connected, for instance, electrically to a part of the basic pressure chamber housing 112 and may thus, for instance, be grounded. Although not illustrated, it is also possible that, optionally, the outer electrode 103 can irradiate a high frequency from the high-frequency source 106 while the gas lance 101 may be grounded, for instance, by an electrical connection to apparatus housing parts or pressure chamber parts.

The suspension of the container 102 by a bottle clamp 110 may be configured to allow a rotation of the container 102, e.g. about its longitudinal axis in the gravity direction. It is also possible to rotate the gas lance 101, preferably during the coating treatment, for instance, about the longitudinal axis thereof in the gravity direction.

The gas lance 101 is designed, for instance, as a hollow cathode along its entire length and may comprise bores or recesses, respectively, e.g. lateral bores 113 and/or axial bores 114, with bore diameters >0.5 mm, preferably 1-2 mm. Also, the hollow-cathode outlet opening 120 at the end of the gas lance 101 may only be a single, simple opening, or comprise a meshed structure. Process gas may be introduced into the container 102 through the bores 113, 114. Also, a generated hollow-cathode plasma 115 can propagate from the interior of the gas lance 101 or the interior of the hollow cathode through the bores/recesses 113,114 into the interior of the container 102 and support or intensify a process gas plasma 116 which may already be present in the interior of the container 102, or ignite the process gas, to more effectively convert the process gas and precipitate a coating on the inner wall of the container 102.

The apparatus of FIG. 1 may be realized in the form of a carousel on which the containers 102 can be guided on a circular segment path whilst traveling through the plasma treatment area.

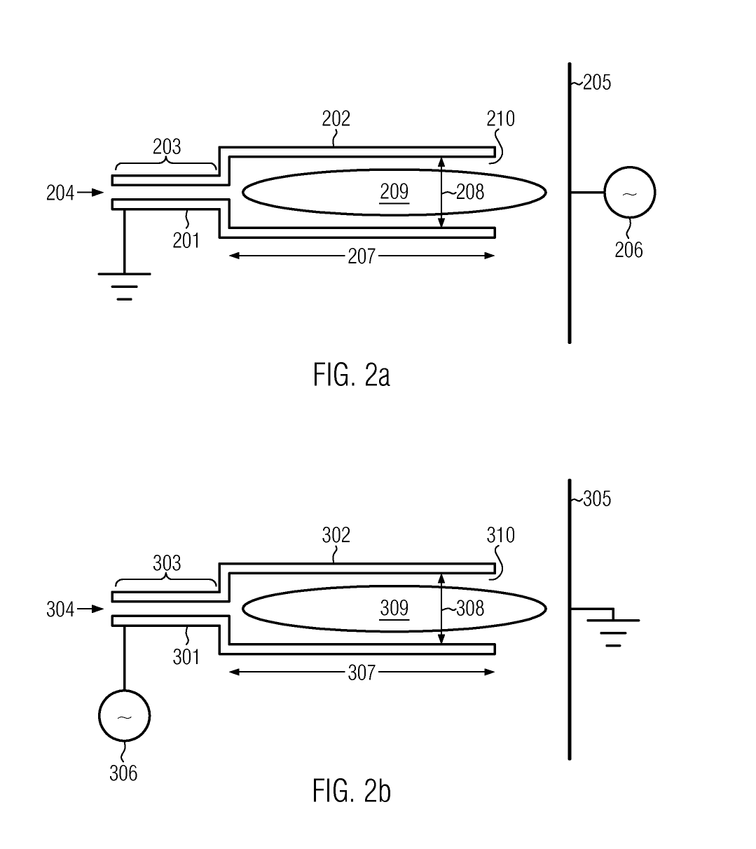

FIG. 2a shows by way of example the basic structure of the gas lance 201 with a hollow cathode 202, in which high frequency from a high-frequency source 206 can be irradiated by an outer electrode 205 and couple to an electrically conducting, grounded gas lance 201. The end of the gas lance 201 may be formed as a hollow cathode 202. The length 207 and the width or internal diameter 208, respectively, of the internal hollow space of the hollow cathode 202 may advantageously be adapted to the pressure in the interior of the hollow cathode 202, allowing to ignite a hollow-cathode plasma 209 more easily and maintain it. For instance, according to the before-mentioned Paschen curve relation, the internal hollow space of the hollow cathode may have an internal diameter 208 between 1 cm≦d≦10 cm for a pressure of 100 Pa or, respectively, an internal diameter 208 <1 cm for pressures >100 Pa so as to minimize the necessary breakdown voltage.

By part 203 of the gas lance 201 not formed as a hollow cathode gas, for instance process gas, can be supplied to the internal hollow space of the hollow cathode. The hollow-cathode plasma 209 can flow out, for instance, through the hollow-cathode outlet opening 210.

The exemplary basic structure of a gas lance 301 with a hollow cathode 302 as shown in FIG. 2b is identical with the structure shown in FIG. 2a, except for the fact that the outer electrode 305 may, in this case, be grounded and the high frequency from the high-frequency source 306 can be irradiated by the gas lance 301.

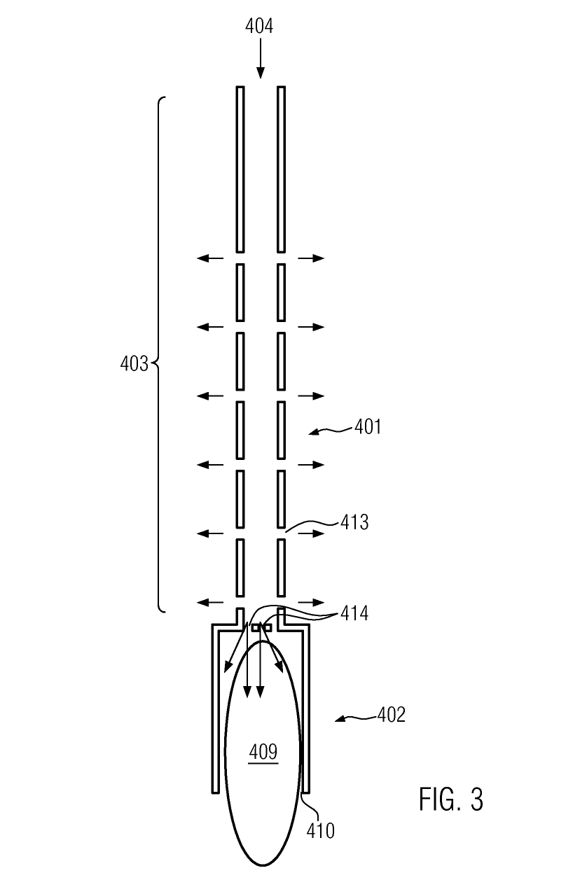

FIG. 3 shows by way of example a gas lance 401 whose end may be a hollow cathode 402. Part 403 of the gas lance not formed as a hollow cathode may comprise lateral 413 and/or axial 414 bores or recesses, through which gas 404, e.g. process gas, can be supplied into the interior of the container 102 and into the interior of the hollow cathode 402. The average bore diameters or recess diameters may be >0.5 mm, preferably 1-2 mm.

It is also conceivable, however, that average bore or recess diameters <0.5 mm may be used so as to minimize or even suppress a formation or propagation of a hollow-cathode plasma 409 inside part 403 of the gas lance 401 not formed as a hollow cathode, and be able to confine the discharge of the hollow-cathode plasma 409 to the hollow-cathode outlet opening 410.

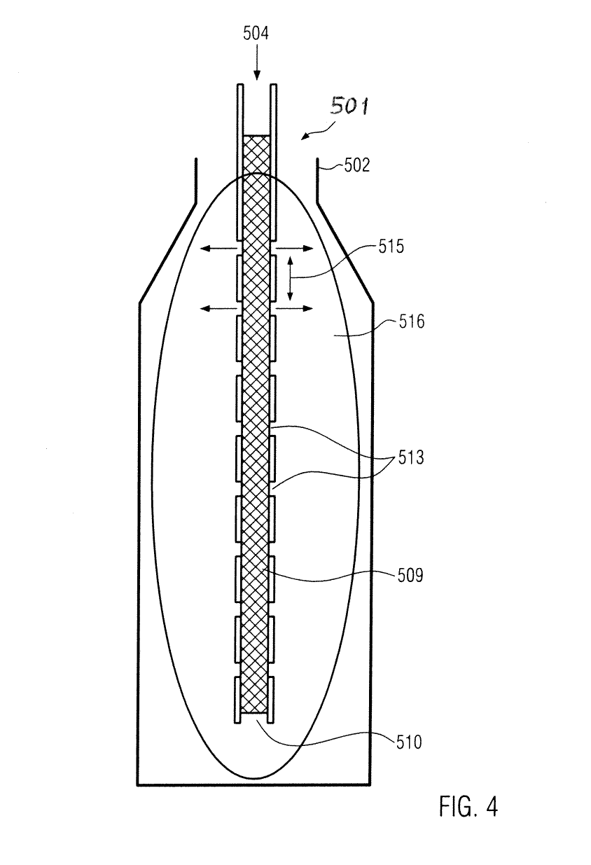

FIG. 4 shows by way of example a gas lance 501 which may be designed as a hollow cathode along its entire length. The gas lance 501 may comprise bores/recesses, preferably lateral bores 513. The average bore diameters or recess diameters may preferably be >0.5 mm, preferably 1-2 mm. The distances between the bores 513 may be regular or irregular. Preferably, they can be for example regular at 20 mm. As illustrated, the end of the gas lance 501 or the hollow-cathode outlet opening 510, respectively, may be entirely open, or have axial bores/recesses (not illustrated), e.g. with average bore diameters or recess diameters of >0.5 mm, preferably 1-2 mm.

Gas 504, e.g. process gas, can be supplied into the interior of the gas lance 501 or hollow cathode along the entire length of the gas lance 501, and can distribute through the aforementioned bores/recesses 513 into the interior of the container 502.

Also, a generated hollow-cathode plasma 509 can propagate into the interior of the container 502 along the entire length of the gas lance 501 and thus possibly mix with an already present process gas plasma 516, or ignite the process gas plasma 516, so as to be able to coat the container 502 more effectively.

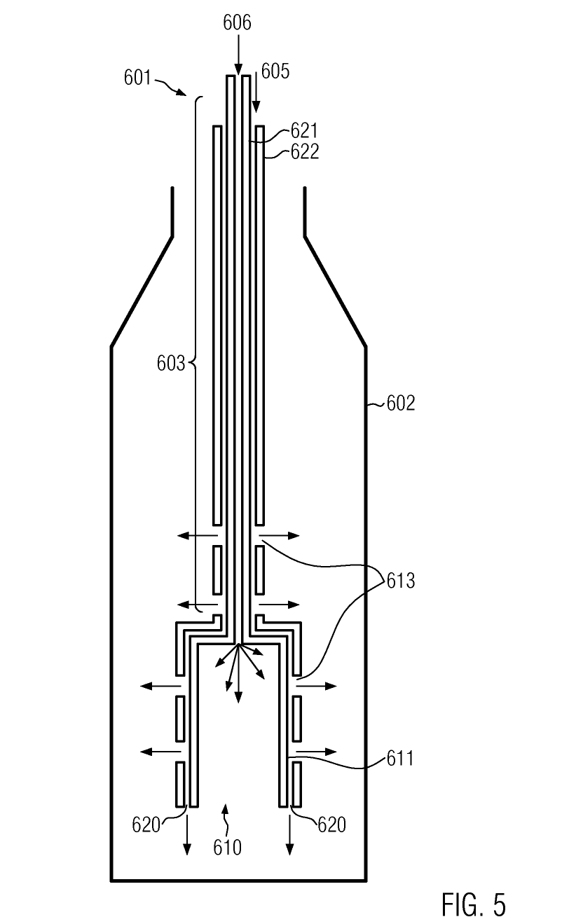

FIG. 5 shows by way of example a gas lance 601 by means of which a process gas 605 can be conducted into the interior of the container 602 and, at the same time, a neutral, non-coating inert gas 606, such as argon or a mixture of oxygen or argon, can be conducted into the interior of the hollow cathode/into the internal hollow space of the hollow cathode 611 physically separated from the process gas 605, for instance, in order to advantageously increase the pressure in the interior of the hollow cathode 611 so as to reduce the necessary breakdown voltage and minimize undesired coatings in the interior of the hollow cathode 611 and in the interior of the gas lance 601. To this end, the gas lance 601 may, for instance, be formed of two parts placed inside each other. By an inner gas lance 621, for instance, said neutral, non-coating inert gas 606 may be conducted into the hollow cathode/into the internal hollow space of the hollow cathode 611 of the inner gas lance 621. Generated hollow-cathode plasma can flow through the hollow-cathode outlet opening 610 of the inner gas lance 621 into the interior of the container 602.

At the same time, process gas 605, e.g. a mixture of HMDSO and oxygen or mixtures of oxygen and other silicon-containing monomers, may be supplied by an outer gas lance 622 into the interior of the container 602 by allowing the process gas 605 to flow out of lateral bores/recesses 613, for instance, with average bore diameters or recess diameters <0.5 mm, preferably 0.1-0.2 mm, so as to be able to suppress a plasma ignition in the process gas carrying part of the gas lance 601, and/or out of at least one axial bore or axial outlet opening 620 of the inner gas lance 621 into the interior of the container.

The outer gas lance 622 may, in this case, be adapted in part or in whole to the contour of the inner gas lance 621. For instance, the distance between the inner gas lance 621 and the outer gas lance 622 may be constant, except for a tolerance, for instance of 10, 20 or 50%.

1. An apparatus for coating a container, by means of a plasma treatment, the apparatus comprising:
at least one high-frequency source, at least one outer electrode located outside the container to be treated, and at least one at least partially electrically conducting gas lance for the supply of process gas into the container, configured to apply a high frequency of the high frequency source to the at least one outer electrode or the at least one gas lance, wherein the at least one gas lance is configured at least in part or in whole as a hollow cathode having at least one internal hollow space, wherein the at least one hollow space of the hollow cathode is fluidically connected to the interior of the container to be treated and to a part of the gas lance that supplies the process gas by at least one of lateral bores and axial bores, and that a plasma can be generated in the interior of the hollow cathode in the at least one hollow space.

2. An apparatus according to claim 1, the wherein a part of the gas lance that is not configured as a hollow cathode is provided with bores which are arranged on at least one of the side and axially through which process gas can be supplied into the interior of the container and/or into the at least one hollow space of the hollow cathode.

3. An apparatus according to claim 1 wherein the gas lance comprises an internal hollow space along the entire length of the gas lance and the internal hollow space is provided with bores.

4. An apparatus according to claim 1, wherein the gas lance is mounted rotatably.

5. An apparatus according to claim 1, wherein the gas lance is adapted to allow the physically separated supply of process gas and a neutral, non-coating inert gas, wherein the process gas can be supplied directly to the container and the neutral, non-coating inert gas can be supplied directly to the hollow cathode.

6. An apparatus according to claim 5, wherein the gas lance comprises an inner gas lance by means of which the neutral, non-coating inert gas can be supplied into the internal hollow space of the hollow cathode of the inner gas lance and an outer gas lance by means of which process gas can be supplied into the interior of the container by allowing the process gas to flow out of lateral bores and/or out of at least one axial bore or axial outlet opening of the inner gas lance (621) into the interior of the container.

7. An apparatus according to claim 6, wherein the outer gas lance is adapted at least partly to a contour of the inner gas lance.

8. A method for the plasma-enhanced coating of a container, the method comprising: converting a process gas at least in part with a hollow-cathode plasma generated in a gas lance according to claim 1.

9. An apparatus according to claim 1, wherein the container is a plastic bottle.

10. An apparatus according to claim 2, wherein the bores have an average bore diameter less than approximately 0.5 mm.

11. An apparatus according to claim 3, wherein the internal hollow space has an average internal diameter of 2-20 mm along the entire length of the gas lance.

12. An apparatus according to claim 3, wherein the length of the gas lance is between about 50 mm and about 500 mm.

13. An apparatus according to claim 3, wherein the bores are arranged on either or both of on a side of the gas lance or axially on the gas lance.

14. An apparatus according to claim 1, wherein the gas lance is adapted to allow the physically separated supply of process gas and a neutral, non-coating inert gas, wherein the process gas can be supplied directly to the container and the neutral, non-coating gas can be supplied directly to the internal hollow space.
